(19) United States
(12) Patent Application Publication
(10) Pub. No.: US 2010/0302085 A1
(43) Pub. Date: Dec. 2, 2010

(54) Field Device Having an Analog Output

(75) Inventors: Eric Chemisky, Soultz sous forets (FR); Michael Geppert, Ottersweier (DE); Ulrich Hahn, Lebach (DE); Simon Rohrbach, Karlsruhe (DE)

Correspondence Address: COHEN, PONTANI, LIEBERMAN & PAVANE LLP, 551 FIFTH AVENUE, SUITE 1210, NEW YORK, NY, 10176, US

(73) Assignee: Siemens AG, Munchen (DE)

(21) Appl. No.: 12/680,432

(22) PCT Filed: Sep. 26, 2008
(86) PCT No.: PCT/EP2008/062946

§ 371 Date: May 12, 2010

(30) Foreign Application Priority Data
Sep. 28, 2007 (DE) 10 2007 046 560.4

(51) Int. Cl. H03M 1/66

(52) U.S. Cl. 341/145

(57) ABSTRACT

A field device having an analog output, i.e., a measuring transducer, for process instrumentation having a 4-20 mA interface as the analog output. For digital-to-analog conversion, a digital value is split into a digital coarse portion and a digital fine portion. Depending on the digital coarse portion, a first analog signal is generated using a pulse width modulator having a downstream mounted low path filter and a signal above the analog output signal, and a second output signal using a pulse width modulator also having a downstream mounted low path filter with a signal below the analog output signal. The analog signals are supplied to a third pulse width modulator controlled with the digital fine portion, where a low-pass filter (TP3) is downstream mounted. As a result, an analog output signal is provided having a high resolution and good dynamic properties. In addition, the field device is provided with a digital-to-analog converter that can be produced having minimal complexity.

### CROSS-REFERENCE TO RELATED APPLICATIONS

This is a U.S. national stage of International Application No. PCT/EP2008/062946, filed on 26 Sep. 2008. Priority is claimed on German Application No. 10 2007 046 560.4, filed on 28 Sep. 2007.

### BACKGROUND OF THE INVENTION

1. Field of the Invention

The invention relates to a field device having an analog output, and, more particularly, to a measuring transducer for process instrumentation having a 4-20 mA interface as the analog output.

2. Description of the Related Art

DE 199 30 661 A1 discloses field devices having analog outputs. In process instrumentation, measuring transducers having a 4-20 mA interface are used in a multiplicity of applications for measuring physical or chemical variables, such as pressure, temperature or a pH value. The transducers typically have a sensor whose sensor signal is amplified, digitized, and subsequently analyzed in a microcontroller to correct the linearity and temperature characteristics. The sensor signal conditioned in this manner is converted in an output circuit comprising a digital/analog converter into an analog output signal, e.g., into an output current in the range of 4-20 mA, and transmitted over a two-wire line to an analyzer device, such as a programmable logic controller in an automation network.

On the other hand, a programmable logic controller comprising a field device can have an analog output, for example, for passing an actuating variable to a control valve as an actuating element having a corresponding analog input.

Digital/analog converters having different principles of operation are known for generating the analog output signal. For example, digital/analog converters having an R2R network and implemented as integrated components are available. What is disadvantageous with components of this type, however, are the costs associated therewith, as well as their high electric power consumption. In particular, in cases where field devices are supplied with the energy required for their operation via a 4-20 mA interface, a significant disadvantage is created because the available energy is very limited. A further possibility for digital/analog conversion can be seen in the use of a timer output of the microcontroller for controlling a pulse width modulator to which a high-precision reference voltage is supplied, and downstream of which a low-pass filter is connected for smoothing the output signal. However, this arrangement is problematic in that a compromise must be made between the achievable dynamics and the adjustment precision of the analog signal, because the frequency of the pulse-width-modulated signal, which frequency has a direct impact on the dynamics, results from the bit resolution of the digital/analog conversion and the clock rate of the microcontroller and is proportional to the product of these two variables. The clocking of the microcontroller has a direct effect on its power consumption and cannot be increased at will. On the other hand, the frequency of the pulse-width-modulated signal cannot be arbitrarily reduced in order to achieve a higher bit resolution, because this is a determinant factor in the dynamics of the generated analog output signal.

### SUMMARY OF THE INVENTION

It is therefore an object of the invention to provide a field device having an analog output, i.e., a measuring transducer for process instrumentation having a 4-20 mA interface as the analog output, which has a low power consumption and by which a high-resolution analog output signal having a greater dynamic range can be generated.

This and other objects and advantages are achieved in accordance with the invention by a field device in which the conflict between the dynamics and precision of the analog output signal is resolved by a stage-by-stage digital/analog conversion. For that purpose, two analog signals having lower resolution are initially generated in a first stage, where the signals are above and below the desired analog output signal. In a second stage connected downstream thereof, the signals are used as voltage levels for generating a pulse-width-modulated signal whose pulse-pause ratio only has to be set with a precision that corresponds to the further resolution that is still to be achieved in relation to the coarse resolution.

In accordance with the invention, each stage handles a part of the resolution. Consequently, substantially higher dynamics can be achieved when a microcontroller is used to generate the time signals for the pulse width modulation at the same clock rate. On the other hand, the microcontroller can now be clocked at a lower frequency to achieve predefined dynamics, with the result that the energy consumption of the microcontroller drops and consequently more energy is available for the actual measurement function of a measuring transducer. This can be used to improve the measurement accuracy of the measuring transducer.

A microcontroller is already present in the majority of field devices. As a result, a particularly simple implementation of the digital/analog converter can be achieved if the digital/analog converter is suitably programmed to split the digital value into a digital coarse portion and a digital fine portion and generates the time signals required for controlling the pulse width modulators.

A particularly high level of precision of the digital/analog conversion is advantageously possible if the low-pass filters of the digital/analog converter are implemented using passive components and are dimensioned such that their input resistance is substantially higher in comparison to the output resistance of the pulse width modulators.

In order to ensure that poor dynamics of one stage do not have an unfavorable effect on the overall dynamics of the digital/analog conversion, the dynamics of the stages should optimally be identical. This can be achieved in a simple manner if the resolution of the coarse portion and the resolution of the fine portion correspond to the same number of bits. This means that the digital coarse portion essentially corresponds to the N most significant bits and the digital fine portion essentially corresponds to the m least significant bits of the digital value and N is approximately equal to m. Noise in the analog output signal can largely be avoided if the coarse portion is generated using hysteresis.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention and embodiments and advantages are explained in more detail below with reference to the drawings, in which an exemplary embodiment of the invention is depicted and, in which:

FIG. 1 shows a schematic layout of a measuring transducer;

FIG. 2 shows a block diagram of a digital/analog converter;

FIG. 3 shows a timing diagram to explain its principle of operation; and

FIG. 4 shows a circuit of a digital/analog converter.

### DESCRIPTION OF THE PREFERRED EMBODIMENTS

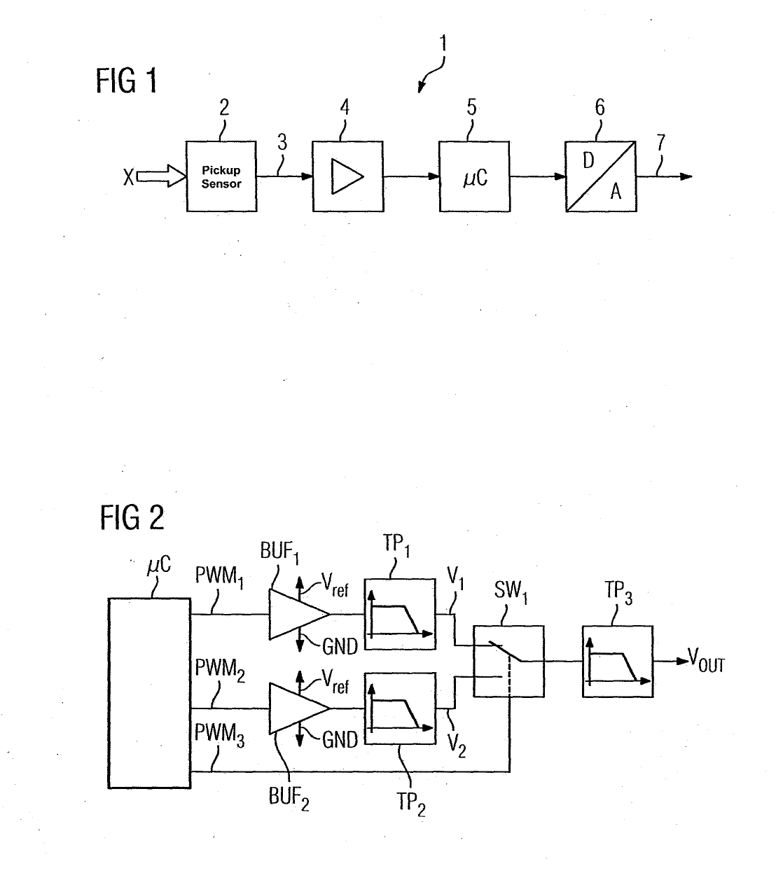

With reference to FIG. 1, a measuring transducer 1 for measuring a physical or chemical variable X of a process has a pickup sensor 2 which converts the variable into a measurement signal 3. The measurement signal 3 is amplified and digitized in a preprocessing stage 4. The measurement signal preprocessed in this way is supplied in digital form to a microcontroller 5 which, for example, compensates for non-linearities and temperature effects and calculates the measured value to be output. The digital measured value calculated in the microcontroller 5 is converted in a digital/analog converter 6 into an analog output signal which is output via a 4-20 mA interface 7 for further use in a process engineering plant in which the measuring transducer 1 is used.

For purposes of digital/analog conversion, a microcontroller μC shown in FIG. 2 generates three time signals PWM₁, PWM₂ and PWM₃. The time signals PWM₁ and PWM₂ are determined in accordance with a coarse portion of the digital value, while the time signal PWM₃ is determined in accordance with a digital fine portion. A buffer BUF₁, which has the function of a pulse width modulator, generates a pulse-width-modulated signal corresponding to the time signal PWM₁ and whose upper level is a reference voltage V_{ref} and whose lower level is the reference ground GND. The signal is smoothed in a low-pass filter TP₁ such that a first analog signal V₁ is present which is higher than the desired analog output signal V_{OUT}. A second analog signal V₂ whose level is lower than the desired output signal V_{OUT} is generated in a similar manner with the aid of the time signal PWM₂, by a buffer BUF₂ and by a low-pass TP2. The time signal PWM₃, which corresponds to the digital fine portion of the digital value, is used to control a changeover switch SW₁ which therefore also has the function of a pulse width modulator. The first analog signal V₁ and the second analog signal V₂ are supplied to the changeover switch SW₁. The pulse-width-modulated signal is then smoothed by a low-pass TP₃ which is connected downstream of the changeover switch SW₁, with the result that the analog output signal Vₒᵤᵣ is finally present.

An example of a digital/analog conversion having 17-bit resolution is described below. The coarse and fine portions have a resolution of 9 bits. A resolution of one bit which remains in a summation of the resolutions of coarse and fine portion in relation to the resolution of the digital value is required, as will be explained later, for realizing a hysteresis of the coarse portion.

The first analog signal V₁ can be calculated according to the formula:

$${V}_{1} = {V}_{ref} \frac{{N}_{1}}{{2}^{9}} .$$

Here, N₁ essentially corresponds to the most significant bits of the digital value and has a value range of between 0 and 2⁹−1.

The level of the second analog signal V₂ can be calculated according to the formula:

$${V}_{2} = {V}_{ref} \cdot \frac{{N}_{2}}{{2}^{9}} .$$

Here, N₂ likewise corresponds largely to the most significant bits of the digital value and has the same value range as N₁ i.e., 2⁹−1. As explained in more detail below, a hysteresis is used in order to avoid noise in the analog output signal V_{OUT}. For that purpose the following is specified:

N₁=N₂+2.

In accordance with the time signal PWM₃, a switch is performed between the first analog signal V₁ and the second analog signal V₂ with the aid of the changeover switch SW₁ The level of the analog output signal V_{OUT} can be calculated according to the formula:

$${V}_{OUT} = \frac{{V}_{ref}}{{2}^{18}} \cdot ( m \cdot {N}_{1} + {2}^{9} \cdot {N}_{2} - m \cdot {N}_{2} ) .$$

Here, the value m corresponds to the fine portion specified with the aid of the microcontroller μC and used to set the timer for generating the time signal PWM₃. The value m also has a value range of between 0 and 2⁹−1. If N₂+2 is substituted for N₁ and N for N₂ in the last formula, then the following relationship is obtained for the level of the analog output signal V_{OUT}:

$${V}_{OUT} = \frac{{V}_{ref}}{{2}^{17}} \cdot ( m + {2}^{8} \cdot N ) .$$

Thus, the result is a digital/analog conversion having 17-bit resolution, where the value m corresponds to the least significant bits and the value N to the most significant bits.

The digital values calculated for the coarse portion and the fine portion in the microcontroller μC do not have to correspond exactly at every instant in time to the most significant bits or least significant bits of the digital value, but are set different from these under certain conditions. The analog output voltage is set with the aid of the time signal PWM₂, which corresponds to the digital fine portion, as a function of the first analog signal V₁ and the second analog signal V₂. If the value of the nine least significant bits is close to its limits, i.e., close to the value 0 or close to the value 2⁹−1, it could happen if these limits are exceeded in the absence of hysteresis that the digital coarse portion, and hence the two analog signals V₁ and V₂ constantly switch back and forth. As a result, unnecessary noise is created in the analog output signal V_{OUT}.

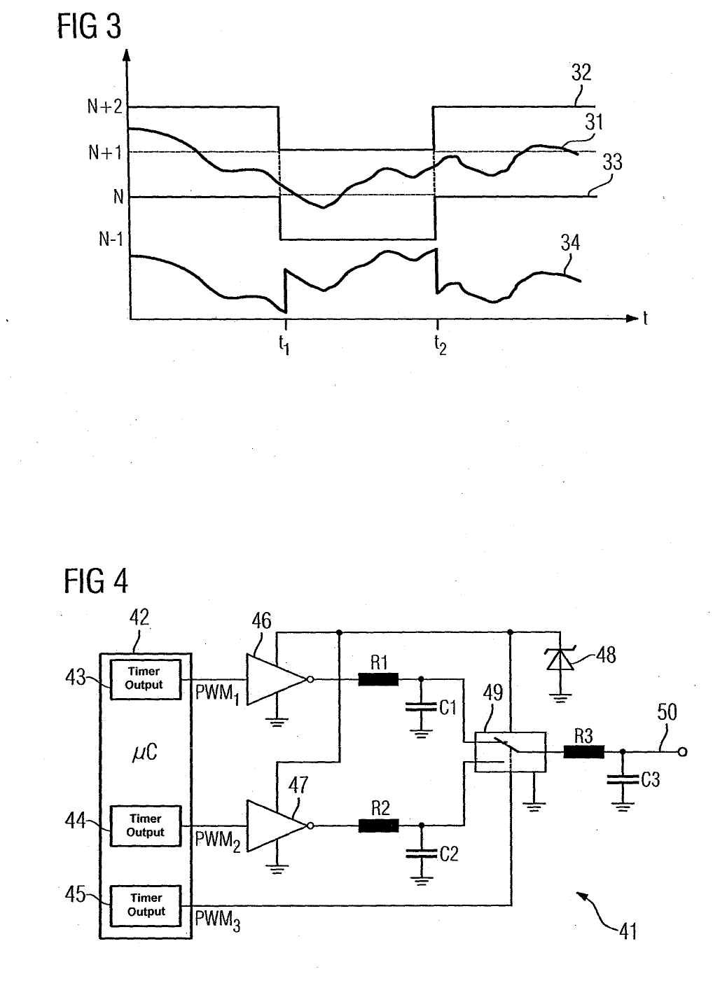

In order to prevent the creation of unnecessary noise in the output value V_{OUT}, instead of the values 0 and 2⁹−1 being used as switchover points of the digital fine portion, a value at 12.5% and a value at 87.5% of the overall value range of the digital fine portion is used, e.g., the values 64 and 448, respectively, in a value range of 512. This is explained in more detail below with reference to FIG. 3. FIG. 3 is a timing diagram in which a curve 31 of an analog output signal V_{OUT}, a curve 32 of a first analog signal V₁, a curve 33 of a second analog signal V₂ and a curve 34, which corresponds to the respective digital fine portion, are plotted over time. In the left-hand range for times t<t₁, the digital coarse portion is set to the value N. The value N₂ for setting the time signal PWM₂ is equal to N, while the value N₁ for setting the time signal PWM₁ equals N+2. This setting of the digital coarse portion remains constant as long as the digital fine portion stays within its limits between 12.5% and 87.5% of the value range. At the time t₁, the digital value drops to such an extent that the digital fine portion falls below the 12.5% limit and accordingly the analog output signal 31 approaches the second analog signal 33. As a result, the values N₁ and N₂ are decremented by 1 in the switchover point at the time t₁. At the same time, the digital fine portion is increased by approximately 50% of its value range, such that no switchover jump is detectable in the curve of the analog output signal 31. The new value m_{NEW} of the digital fine portion is yielded according to the formula:

m_{NEW}=m_{OLD}+2⁸.

Thus, m_{NEW} amounts to approximately 62.5% and lies below the 87.5% limit at which the values N₁ and N₂ would be increased by 1 again. A hysteresis is therefore realized by which noise at the switchover points is prevented.

According to the curve 34 the digital fine portion exceeds the 87.5% limit of its value range at the second switchover point t₂. This is followed immediately by an incrementation of the values N₁ and N₂ by 1 and a reduction in the digital fine portion by 2⁸. Directly following the switchover, the value of the digital fine portion equals approximately 37.5% of its value range.

The splitting of the digital value corresponding to the analog output signal V_{OUT} into the digital coarse portion and the digital fine portion with hysteresis of the coarse portion is performed in the microcontroller μC based on its programming. Advantageously, no overhead in terms of additional circuitry is associated therewith.

FIG. 4 shows a circuit 41 suitable for implementing the digital/analog converter. Here, the microcontroller comprises integrated chipset 42 of the MSP430 type which has three timer outputs 43, 44 and 45 that are used for implementing the pulse-width-modulated time signals PWM₁, PWM₂ and PWM₃, respectively. The time signals PWM₁ and PWM₂ are supplied to two buffers 46 and 47, respectively, of the 74LVC04 type which are supplied with a high-precision reference voltage by a diode 48. Connected downstream of the buffers 46 and 47 there is, respectively, a low-pass stage consisting of a resistor R₁ and a capacitor C1 and a low-pass stage consisting of a resistor R₂ and a capacitor C₂. Each of the resistors have an exemplary value of 51 kΩ, each of the capacitors have an exemplary value of 33 nF. The analog signals smoothed in this way are supplied to two inputs of a changeover switch 49 of the 3157 type from Texas Instruments. The time signal PWM₃ serves to actuate the changeover switch 49. Connected in circuit downstream of the changeover switch 49 is a low-pass stage comprising a resistor R₃ having an exemplary value of 150 kΩ and a capacitor C3 having an exemplary value of 100 nF. This low-pass stage, finally, provides an analog output signal 50 corresponding to the predefined digital value. Passive RC filters are intentionally used for implementing the low-pass stages, as opposed to circuits having active components, because the filters offer a very high level of precision. Here, it is important that the output resistance of the buffers 46 and 47 and the output resistance of the changeover switch 49 are small in comparison to the input impedance of the downstream-connected low-pass in each case.

It emerges particularly clearly from the circuit according to FIG. 4 that the digital/analog converter can be manufactured particularly economically with the circuit 41 shown therein. In spite of the high overall resolution of the digital/analog converter, time signals PWM₁, PWM₂ and PWM₃ having a comparatively high frequency can be used for generating the analog output signal owing to the sequentially connected stages. This leads to high dynamics of the digital/analog conversion.

Thus, while there have been shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-4. (canceled)

5. A field device having an analog output and a digital/analog converter for generating an analog output signal at the analog output, comprising:
a device for splitting a digital value into a digital coarse portion and a digital fine portion;
a first circuit having a first pulse width modulator settable as a function of the digital coarse portion and configured to connect to a reference voltage, and a first low-pass stage connected downstream of the first pulse width modulator for generating a first analog signal having a level above the level of the analog output signal of the analog output;
a second circuit having a second pulse width modulator settable as a function of the digital coarse portion and configured to connect to the reference voltage, and a second low-pass stage connected downstream of the second pulse width modulator for generating a second analog signal having a level below the level of the analog output signal of the analog output; and
a third circuit having a third pulse width modulator settable as a function of the digital fine portion and configured to receive the first analog signal and the second analog signal, an upper level of an output signal of the third pulse width modulator corresponding to the first analog signal and a lower level of the output signal of the third pulse width modulator corresponding to the second analog signal, and having a third low-pass stage for generating the analog output signal connected downstream of the third pulse width modulator.

6. The field device as claimed in claim 5, wherein the device for splitting the digital value comprises a microcontroller configured to generate a plurality of time signals for controlling the first, second and third pulse width modulators.

7. The field device as claimed in claim 5, wherein the first, second and third low-pass stages comprise passive components such that an input resistance of the first, second and third low-pass stages is substantially greater than an output resistance of the first, second and third pulse width modulators.

8. The field device as claimed in claim 6, wherein the first, second and third low-pass stages comprise passive components such that an input resistance of the first, second and third low-pass stages is substantially greater than an output resistance of the first, second and third pulse width modulators.

9. The field device as claimed in claim 5, wherein the device for splitting the digital value into the digital coarse portion and the digital fine portion is configured such that the digital coarse portion essentially corresponds to the most significant bits of the digital value and the digital fine portion essentially corresponds to the least significant bits of the digital value, a number of the most significant bits and the number of the least significant bits is approximately equal; and wherein generation of the coarse portion includes a hysteresis.

10. The field device as claimed in claim 5, wherein the field device comprises a measuring transducer for process instrumentation having a 4-20 mA interface at the analog output.
